(19) United States
(12) Patent Application Publication
(10) Pub. No.: US 2025/0210473 A1
(43) Pub. Date: Jun. 26, 2025

(54) LEAD FRAME AND SEMICONDUCTOR DEVICE

(71) Applicant: SHINKO ELECTRIC INDUSTRIES CO., LTD., Nagano (JP)

(72) Inventor: Shintaro HAYASHI, Nagano (JP)

(21) Appl. No.: 18/982,156

(22) Filed: Dec. 16, 2024

(30) Foreign Application Priority Data
Dec. 21, 2023 (JP) 2023-215401

(51) Int. Cl. H01L 23/495; H01L 21/48; H01L 21/56; H01L 23/00; H01L 23/31

(52) U.S. Cl. CPC H01L 23/49548; H01L 21/4828; H01L 24/16; H01L 21/56; H01L 23/3107; H01L 2224/16258

(57) ABSTRACT

A lead frame includes a plurality of terminal portions including a first terminal portion, wherein the first portion has an upper surface and at least one side surface, and includes a plurality of bonding areas that are defined on the upper surface within a mounting region where a semiconductor chip is to be mounted, the bonding areas being designated for bonding with respective electrodes of the semiconductor chip, and a recess that is provided between adjacent bonding areas among the plurality of bonding areas and that opens on the upper surface, the recess reaching the at least one side surface.

### CROSS-REFERENCE TO RELATED APPLICATIONS

The present application is based on and claims priority to Japanese Patent Application No. 2023-215401 filed on Dec. 21, 2023, with the Japanese Patent Office, the entire contents of which are incorporated herein by reference.

### FIELD

The disclosures herein relate to lead frames and semiconductor devices.

### BACKGROUND

A semiconductor device known in the art may include a semiconductor chip that is flip-chip mounted on a lead frame and encapsulated with a resin portion (see Patent Document 1, for example). In the manufacturing process of such a semiconductor device, a semiconductor chip is flip-chip mounted on the lead frame, and, then, a resin is injected into a mold, filling a space between the lead frame and the semiconductor chip, followed by curing the resin to form the resin portion for encapsulating the semiconductor chip.

In the semiconductor device as described above, when the gap between the lead frame and the semiconductor chip narrows, the resin may fail to flow smoothly, which may cause a void to be formed in the resin between the lead frame and the semiconductor chip.

Accordingly, there may be a need for a lead frame having a structure that prevents void formation between the lead frame and a semiconductor chip when injecting resin upon mounting the semiconductor chip.

### PRIOR ART DOCUMENT

### Patent Document

[Patent Document 1] Japanese Laid-open Patent Publication No. 2018-190942

### SUMMARY

According to an aspect of the embodiment, a lead frame includes a plurality of terminal portions including a first terminal portion, wherein the first terminal portion has an upper surface and at least one side surface, and includes a plurality of bonding areas that are defined on the upper surface within a mounting region where a semiconductor chip is to be mounted, the bonding areas being designated for bonding with respective electrodes of the semiconductor chip, and a recess that is provided between adjacent bonding areas among the plurality of bonding areas and that opens on the upper surface, the recess reaching the at least one side surface.

The object and advantages of the embodiment will be realized and attained by means of the elements and combinations particularly pointed out in the claims. It is to be understood that both the foregoing general description and the following detailed description are exemplary and explanatory and are not restrictive of the invention, as claimed.

### BRIEF DESCRIPTION OF DRAWINGS

FIGS. 1A and 1B are drawings illustrating an example of a semiconductor device according to a first embodiment;

FIGS. 2A and 2B are drawings illustrating an example of a lead frame according to the first embodiment;

FIG. 3 is a drawing illustrating an example a manufacturing process of the semiconductor device according to the first embodiment;

FIGS. 4A and 4B are diagrams illustrating an example of the manufacturing process of the semiconductor device according to the first embodiment;

FIGS. 5A and 5B are diagrams illustrating an example of the manufacturing process of the semiconductor device according to the first embodiment;

FIGS. 6A and 6B are diagrams illustrating an example of the manufacturing process of the semiconductor device according to the first embodiment;

FIGS. 7A through 7C are diagrams illustrating an example of the manufacturing process of the semiconductor device according to the first embodiment;

FIG. 8 is a drawing illustrating an example of a flow of resin when a resin portion is formed;

FIG. 9 is a drawing illustrating another example of a flow of resin when a resin portion is formed;

FIG. 10 is a plan view illustrating an example of a lead frame according to a first variation of the first embodiment;

FIG. 11 is a plan view illustrating an example of a lead frame according to a second variation of the first embodiment;

FIG. 12 is a plan view illustrating an example of a lead frame according to a third variation of the first embodiment;

FIGS. 13A and 13B are drawings illustrating an example of a lead frame according to a fourth variation of the first embodiment; and

FIG. 14 is a cross-sectional view illustrating an example of a semiconductor device according variation of the first embodiment.

### DESCRIPTION OF EMBODIMENTS

In the following, an embodiment for implementing the invention will be described with reference to the accompanying drawings. In the drawings, the same components are referred to by the same reference numerals, and duplicate descriptions thereof may be omitted.

### First Embodiment

### [Semiconductor Device]

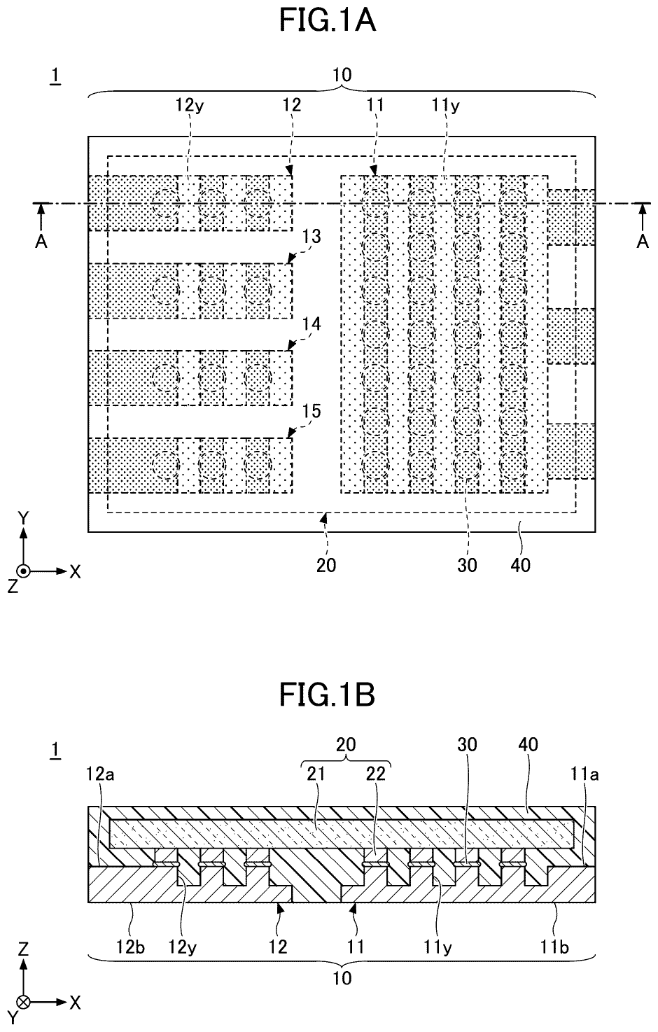

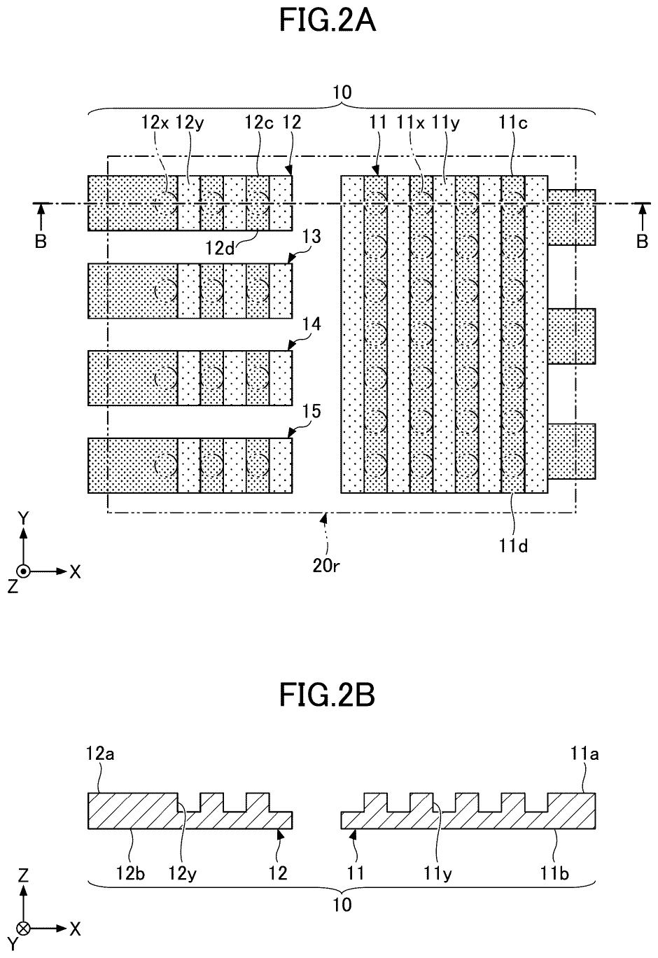

FIGS. 1A and 1B are drawings illustrating an example of a semiconductor device according to a first embodiment. FIG. 1A is a plan view, and FIG. 1B is a cross-sectional view taken along the line A-A in FIG. 1A. FIGS. 2A and 2B are drawings illustrating an example of a lead frame according to the first embodiment. FIG. 2A is a plan view, and FIG. 2B is a cross-sectional view taken along the line B-B in FIG. 2A.

Referring to FIGS. 1A and 1B and FIGS. 2A and 2B, a semiconductor device 1 includes a lead frame 10, a semiconductor chip 20, and a resin portion 40. The semiconductor device 1 is a QFN-type (quad flat no-lead package-type) semiconductor device in which the semiconductor chip 20 is flip-chip mounted on the lead frame 10 and encapsulated with the resin portion 40.

In this embodiment, for the sake of convenience of explanation, the semiconductor chip 20 side of the semiconductor device 1 is referred to an upper side or first side, and the lead frame 10 side is referred to a lower side or second side. The surface of a member on its upper side is referred to the first surface or upper surface, and the surface on the lower side is referred to the second surface or lower surface. However, the semiconductor device 1 may be placed upside down when used, or may be arranged at any angle. The plan view refers to the view of an object as seen from the direction normal to the first surface of the lead frame 10, and the plane shape refers to the shape of an object as seen from the direction normal to the surface of the lead frame 10.

The lead frame 10 has a plurality of terminal portions including a first terminal portion. The thickness of the lead frame 10 may be, for example, about 100 to 200 μm. The material of the lead frame 10 may be, for example, copper (Cu), copper alloy, 42 alloy (i.e., an alloy of Fe and Ni), or the like.

In the example illustrated in FIGS. 2A and 2B, the lead frame 10 includes a first terminal portion 11, a second terminal portion 12, a third terminal portion 13, a fourth terminal portion 14, and a fifth terminal portion 15. The first terminal portion 11 to the fifth terminal portion 15 are spaced from each other and are electrically independent of each other. It may be noted that it does not matter which terminal portion is referred to as the first terminal portion. The number of terminal portions provided may be determined as appropriate.

The first terminal portion 11 has, on the upper surface 11a, a plurality of bonding areas 11x, which are defined in a mounting region 20r where the semiconductor chip 20 is mounted, and which are bonded to the respective electrodes 22 of the semiconductor chip 20. The mounting region 20r is a region which exactly overlaps the semiconductor chip 20 in a plan view, and includes part of the upper surfaces of the terminal portions including the upper surface 11a of the first terminal portion 11.

The first terminal portion 11 has one or more recesses 11y that are provided between adjacent bonding areas 11x and that open on the upper surface 11a. The recesses 11y have a bottom and do not open on the lower surface 11b. The depth of the recesses 11y may be, for example, about half the thickness of the portions of the first terminal portion 11 where the recesses 11y are not formed. The junction between the bottom and side surfaces of each recess 11y may have a corner or a rounded shape. For example, the recesses 11y may each have a U-shape in a cross-sectional view.

Some of the recesses 11y of the first terminal portion 11 reach at least one side surface 11c. In the example illustrated in FIG. 2A, all of the five recesses 11y reach the side surface 11c of the first terminal portion 11. However, it suffices for at least one recess 11y to reach the side surface 11c of the first terminal portion 11. With such a structure, it is less likely for a void to form between the lead frame 10 and the semiconductor chip 20 when the semiconductor chip 20 is mounted and the resin to become the resin portion 40 is injected during the manufacturing process of the semiconductor device 1, as will be described later.

Some of the recesses 11y of the first terminal portion 11 preferably reach the side surface 11c and the other side surface 11d situated opposite the side surface 11c. In the example illustrated in FIG. 2A, all of the five recesses 11y reach the side surface 11d located opposite the side surface 11c of the first terminal portion 11. However, it suffices for at least one recess 11y to reach the side surface 11d of the first terminal portion 11. With this structure, it is possible to further reduce the occurrence of void formation between the lead frame 10 and the semiconductor chip 20.

In the example illustrated in FIG. 2A, the bonding areas 11x are arranged in a matrix of seven rows and four columns in plan view. The X direction is the row direction and the Y direction is the column direction, but the definitions of the row direction and the column direction may be reversed. Preferably, the first terminal portion 11 has at least one recess 11y arranged along a space between adjacent columns. With such a structure, it becomes less likely for a void to form between the lead frame 10 and the semiconductor chip 20.

In the example illustrated in FIG. 2A, each space between the adjacent columns in the first terminal portion 11 has a corresponding one of the recesses 11y arranged therein. With such a structure, it becomes even less likely for a void to form between the lead frame 10 and the semiconductor chip 20. The first terminal portion 11 may have one of the recesses 11y on the outer side of each outermost column located at either end in the row direction (X direction).

The second terminal portion 12 has a plurality of bonding areas 12x, which are defined in the mounting region 20r where the semiconductor chip 20 is mounted on the upper surface 12a, and which are bonded to the respective electrodes 22 of the semiconductor chip 20.

The second terminal portion 12 has one or more recesses 12y that are provided between adjacent bonding areas 12x and that open on the upper surface 12a. The recesses 12y have a bottom and do not open on the lower surface 12b. The depth of the recesses 12y may be, for example, about half the thickness of the portions of the second terminal portion 12 where the recesses 12y are not formed. The junction between the bottom surface and the side surface of each recess 12y may be a corner or rounded shape. For example, the recesses 12y may each have a U-shape in cross-sectional view.

Some of the recesses 12y of the second terminal portion 12 reach at least one side surface 12c. In the example illustrated in FIG. 2A, all of the three recesses 12y reach the side surface 12c of the second terminal portion 12. However, it suffices for at least one recess 12y to reach the side surface 12c of the second terminal portion 12. With such a structure, it becomes less likely for a void to form between the lead frame 10 and the semiconductor chip 20.

Some of the recesses 12y of the second terminal portion 12 reach the side surface 12c and the other side surface 12d opposite the side surface 12c. In the example illustrated in FIG. 2, all of the three recesses 12y reach the side surface 12d opposite the side surface 12c of the second terminal portion 12. However, it suffices for at least one recess 12y to reach the side surface 12d of the second terminal portion 12. With this structure, it is possible to further reduce the occurrence of void formation between the lead frame 10 and the semiconductor chip 20.

In the example illustrated in FIG. 2A, the bonding areas 12x are arranged in a matrix of one row and three columns in plan view. Preferably, the second terminal portion 12 has at least one of the recesses 12y arranged along a space between adjacent columns. With this structure, it becomes less likely for a void to the lead form between frame 10 and the semiconductor chip 20.

In the example illustrated in FIG. 2A, each space between the adjacent columns in the second terminal portion 12 has a corresponding one of the recesses 12y disposed therein. With this structure, it becomes even less likely for a void to form between the lead frame 10 and the semiconductor chip 20. The second terminal portion 12 may have one of the recesses 12y on the outer side of the outermost column situated at the end on the positive X-axis side.

The third terminal portion 13, the fourth terminal portion 14, and the fifth terminal portion 15 each have, on the upper surfaces thereof, a plurality of bonding areas, which are defined in the mounting region 20r where the semiconductor chip 20 is mounted, and which are bonded to the respective electrodes 22 of the semiconductor chip 20. Since the third terminal portion 13, the fourth terminal portion 14, and the fifth terminal portion 15 have the same structure as that of the second terminal portion 12, the description thereof will be omitted.

As illustrated in FIG. 1B, the semiconductor chip 20 is flip-chip mounted on the mounting region 20r of the lead frame 10 in a face-down orientation. The semiconductor chip 20 includes a chip 21 and a plurality of electrodes 22. The chip 21 is structured, for example, such that a semiconductor integrated circuit or the like is formed on a thinned semiconductor substrate made of silicon or the like. The electrodes 22, which are electrically connected to the semiconductor integrated circuit, are formed on the semiconductor substrate. The electrodes 22 are, for example, copper pillars. The height of the electrodes 22 is, for example, about 10 to 20 μm.

The lower surfaces of the electrodes 22 are bonded to the bonding areas 11x of the first terminal portion 11, the bonding areas 12x of the second terminal portion 12, and the bonding areas of the third terminal portion 13 to the fifth terminal portion 15 via a bonding material 30. The bonding material 30 is, for example, solder. The material of the solder is, for example, an alloy containing Pb, an alloy of Sn and Cu, an alloy of Sn and Ag, an alloy of Sn and Ag and Cu, or the like.

The resin portion 40 encapsulates the semiconductor chip 20 on the lead frame 10. The resin portion 40 fills the space where the upper surfaces of the first terminal portion 11 to the fifth terminal portion 15 face the lower surface of the semiconductor chip 20, and the space inside all the recesses including the recesses 11y and 12y. The lower surfaces of the first terminal portion 11 to the fifth terminal portion 15 are exposed outside the resin portion 40. The lower surfaces of the first terminal portion 11 to the fifth terminal portion 15 may be flush with the lower surface of the resin portion 40, for example. Parts of the side surfaces of the first terminal portion 11 to the fifth terminal portion 15 are exposed outside the resin portion 40. The lower surfaces of the first terminal portion 11 to the fifth terminal portion 15 and/or the side surfaces thereof exposed outside the resin portion 40 may be used as external connection terminals, for example. The resin portion 40 may be, for example, a mold resin or the like that is an epoxy resin containing a filler. As an alternative configuration, the resin portion 40 may be formed such that part or all of the upper surface of the chip 21 of the semiconductor chip 20 is exposed.

### [Method of Making Semiconductor Device]

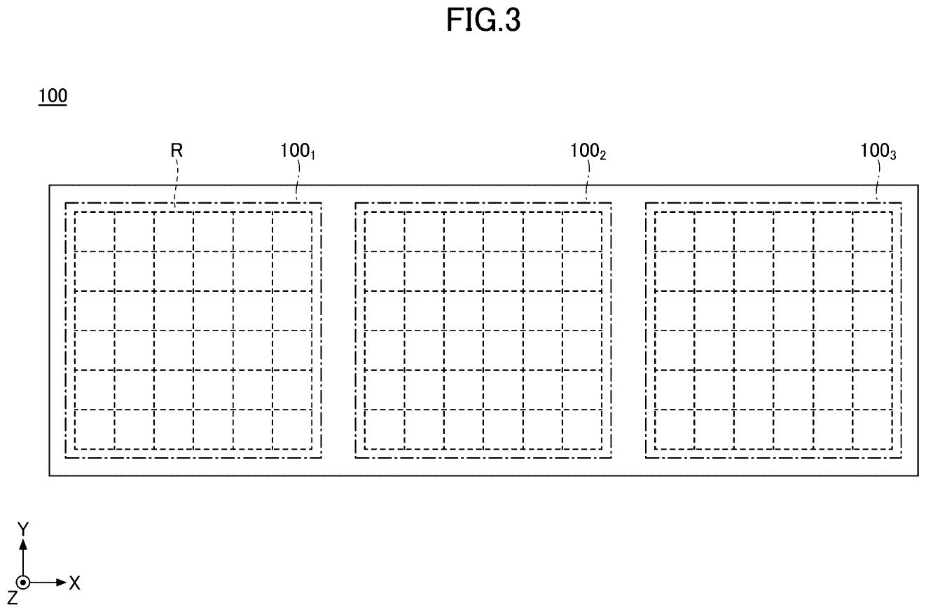

FIGS. 3 to FIGS. 7A through 7C are drawings illustrating an example of the production sequence of the semiconductor device according to the first embodiment.

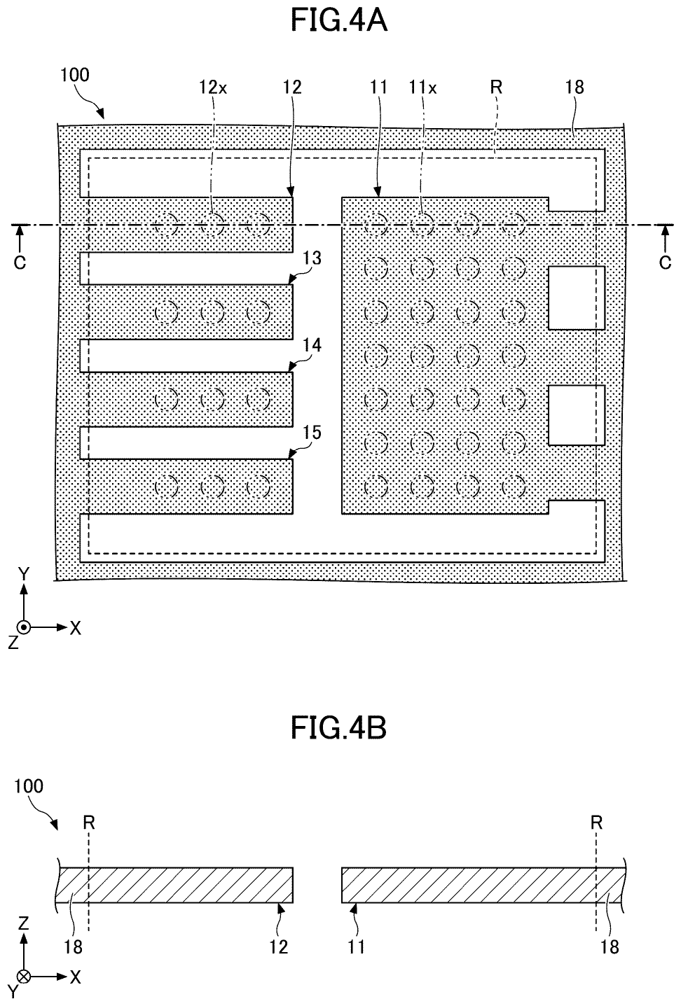

First, in the step illustrated in FIG. 3, a metal plate 100 is prepared. The material and thickness of the metal plate 100 are the same as those of the lead frame 10. In the metal plate 100, for example, three regions 100₁, 100₂, and 100₃ are defined in plan view, and a plurality of regions R each of which becomes the lead frame 10 when singulated are arranged vertically and horizontally in each of the regions 100₁, 100₂, and 100₃. Each region R has a plurality of terminal portions including a first terminal portion. These terminal portions are separate from each other, for example. The number of regions R arranged in each of the regions 100₁, 100₂, and 100₃ may be determined as appropriate. Broken lines indicating the borders of the regions R correspond to positions where the regions R are cut for singulation. Only one region R and its vicinity will be illustrated and described from FIGS. 4A and 4B onwards.

FIGS. 4A and 4B are drawings illustrating an example of one region R and its vicinity. FIG. 4A is a plan view, and FIG. 4B is a cross-sectional view taken along the line C-C in FIG. 4A. In the step illustrated in FIGS. 4A and 4B, each region R is patterned by pressing the metal plate 100. Alternatively, each region R may be patterned by etching the metal plate 100. In each region R, the patterning creates the first terminal portion 11 to the fifth terminal portion 15. The first terminal portion 11 to the fifth terminal portion 15 are linked to and supported by a frame portion 18 that surrounds the first terminal portion 11 to the fifth terminal portion 15. The bonding areas 11x are defined in the first terminal portion 11, and the bonding areas 12x are defined in the second terminal portion 12. Bonding areas are also defined in the third terminal portion 13 to the fifth terminal portion 15.

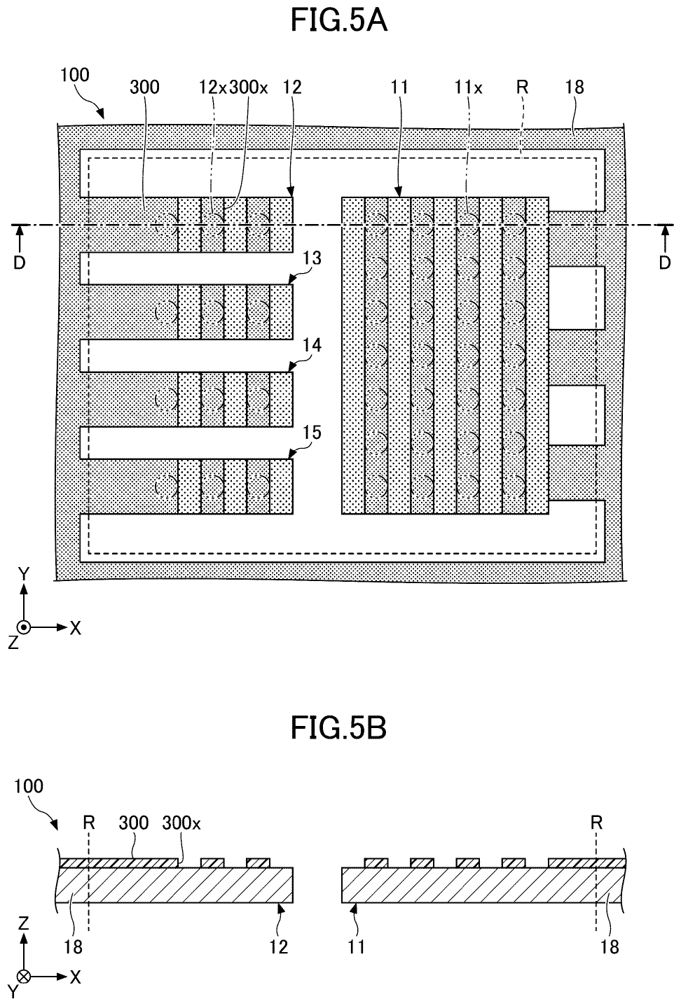

FIGS. 5A and 5B are drawings illustrating an example of one region R and its vicinity. FIG. 5A is a plan view, and FIG. 5B is a cross-sectional view taken along the line D-D in FIG. 5A. In the step illustrated in FIGS. 5A and 5B, a photosensitive resist 300 is formed over the entire upper surface of the first terminal portion 11 to the fifth terminal portion 15 and the frame portion 18 in each region R of the metal plate 100. The resist 300 may be, for example, a dry film resist or an electrodeposition resist. Then, the resist 300 is exposed and developed to form openings 300x in places where the recesses including the recesses 11y and the recesses 12y are formed. At this time, the photosensitive resist 300 may also be formed to cover the entire lower surfaces of the first terminal portion 11 to the fifth terminal portion 15 and the frame portion 18 in each region R of the metal plate 100.

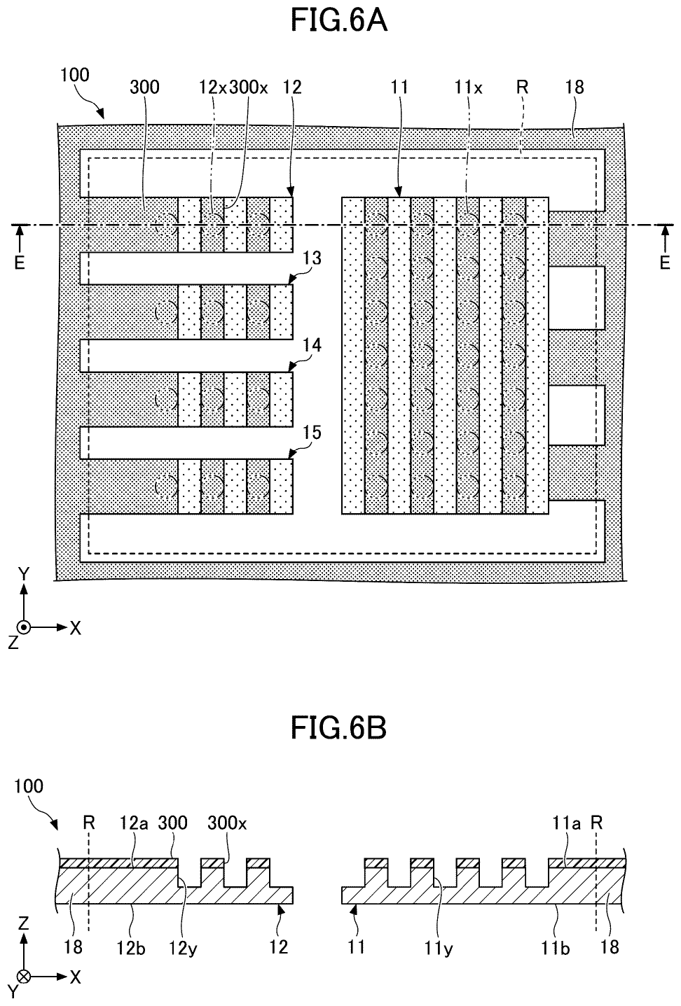

FIGS. 6A and 6B are drawings illustrating an example of one region R and its vicinity. FIG. 6A is a plan view, and FIG. 6B is a cross-sectional view taken along the line E-E in FIG. 6A. In the step illustrated in FIGS. 6A and 6B, each region R of the metal plate 100 is half-etched using the resist 300 as an etching mask. Portions not covered with the resist 300 are half-etched from the upper surface toward the lower surface of the metal plate 100. As a result, the recesses 11y opening on the upper surface 11a and not reaching the lower surface 11b are formed in the first terminal portion 11. Further, the recesses 12y opening on the upper surface 12a and not reaching the lower surface 12b are formed in the second terminal portion 12. Further, the recesses that open on the upper surface and do not reach the lower surface are formed in the third terminal portion 13 to the fifth terminal portion 15. When the metal plate 100 is made of copper, for example, each recess may be formed by wet etching using a cupric chloride aqueous solution.

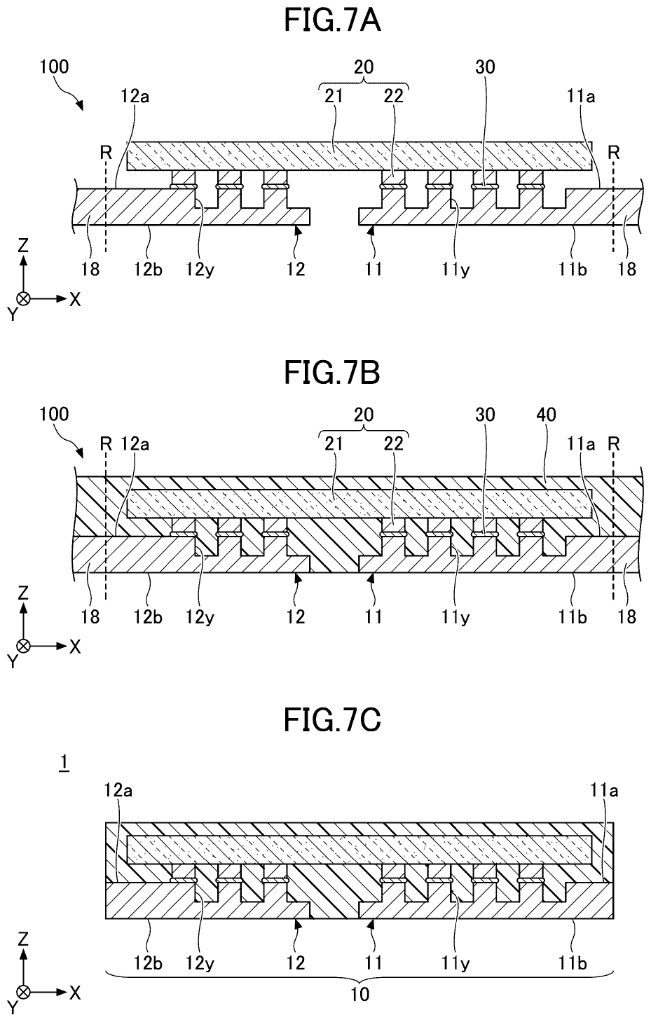

FIGS. 7A through 7C are drawings illustrating an example of one region R and its vicinity, and illustrate cross-sectional views corresponding to FIG. 6B. In the step illustrated in FIG. 7A, after the resist 300 illustrated in FIG. 6B is removed, the semiconductor chip 20 is mounted face-down on each region R of the metal plate 100. Specifically, the electrodes 22 of the semiconductor chip 20 are bonded to the respective bonding areas of the first terminal portion 11 to the fifth terminal portion 15 through the bonding material 30 made of solder or the like.

In the step illustrated in FIG. 7B, the resin portion 40 for encapsulating the semiconductor chip 20 is formed in the regions R of the metal plate 100. The resin portion 40 may be, for example, a mold resin or the like that is an epoxy resin containing a filler. The resin portion 40 may be formed by, for example, a transfer molding method or a compression molding method. The resin portion 40 is formed in each of the regions 100₁, 100₂, and 100₃, for example, illustrated in FIG. 3. Each of the regions 100₁, 100₂, and 100₃ may be simultaneously encapsulated using a mold.

In the step illustrated in FIG. 7C, the structure illustrated in FIG. 7B is cut for singulation at the positions of the broken lines that define the region R. The cutting may be performed by, for example, a slicer or the like. This completes the manufacture of a plurality of semiconductor devices 1.

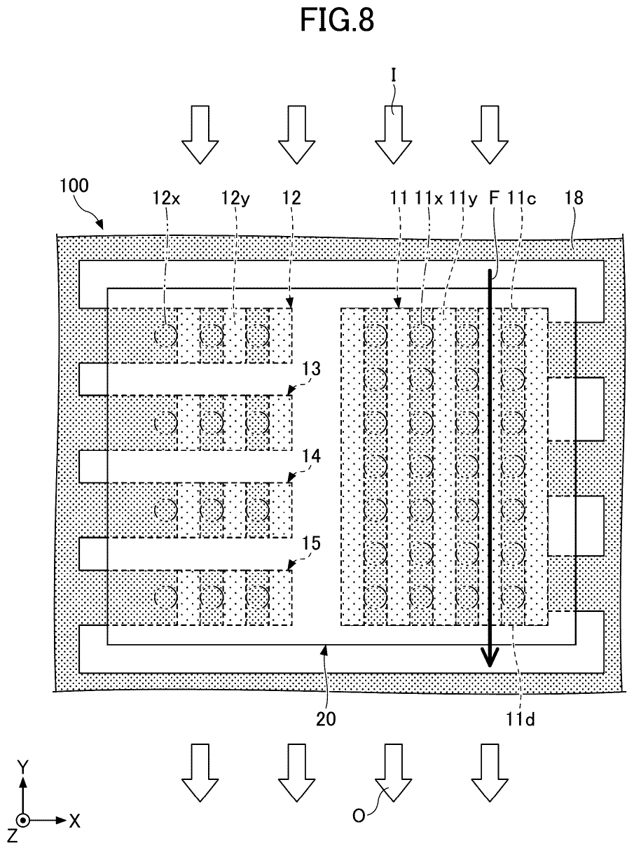

FIG. 8 is a drawing illustrating the flow of resin when the resin portion is formed in the step illustrated in FIG. 7B. In FIG. 8, a plurality of arrows I indicate the direction of injecting resin, which is to become the resin portion 40, into the mold, and a plurality of arrows O indicate the direction of air ventilation. That is, the resin fills the space between each terminal portion including the first terminal portion 11 and the semiconductor chip 20 in each region R of the metal plate 100 while flowing from the direction of the arrow I toward the direction of the arrow O.

The gap between the upper surface 11a of the first terminal portion 11 and the lower surface of the semiconductor chip 20 is approximately determined by the height of the electrodes 22, and is, for example, about 10 to 20 μm. The same applies to the gaps between the other terminal portions and the lower surface of the semiconductor chip 20. Since the gaps are narrow, if the respective terminal portions were not provided with recesses, a void would be highly likely to form in the resin. In particular, in a place like the position of the first terminal portion 11 where the bonding areas 11x were densely packed, void formation in the resin would be more likely.

In the semiconductor device 1, the first terminal portion 11 is configured such that one or more recesses 11y are provided between one or more respective pairs of adjacent bonding areas 11x, and the recesses 11y are arranged so as to reach the pair of opposite side surfaces 11c and 11d of the first terminal portion 11 in a plan view. With this arrangement, the gap between the bottom surface of the recesses 11y and the bottom surface of the semiconductor chip 20 is widened at the positions of the recesses 11y. For example, when the thickness of the first terminal portion 11 is 200 μm, and the height of the electrodes 22 is 20 μm, with the depth of the recesses 11y being 100 μm, the gap between the bottom surface of the recesses 11y and the bottom surface of the semiconductor chip 20 is 120 μm, which is about 6 times as large as the gap of 20 μm, which existed if there were no recesses. This results in an increase in the ease of flow of the resin in the direction of the arrow F, thereby reducing the risk of void formation.

The recesses 11y may be configured such that they reach only the side surface 11c of the first terminal portion 11. In this case, the side of the recesses 11y reaching the side surface 11c is oriented toward the direction from which the resin is injected, so that there is still an improvement in the ease of resin flow, which thus reduces the risk of void formation. Since air is able to escape even through a small gap along the air ventilation path, the ease of resin flow is effectively improved even when the recesses 11y do not reach the side surface 11d. However, provision of the recesses 11y reaching both of the side surfaces 11c and 11d can further improve the ease of resin flow because the air escapes more easily through the air ventilation path.

As in the example illustrated in FIG. 8, it is preferable that the recesses 11y are arranged between all the adjacent columns of the bonding areas 11x. This further increases the ease of resin flow, thereby further reducing the risk of void formation.

Since the bonding areas of the second terminal portion 12 to the fifth terminal portion 15 are not densely packed as compared with the first terminal portion 11, no recesses need to be provided, but the provision of one or more recesses effectively improves the ease of resin flow.

### Variations of First Embodiment

Variations of the first embodiment are directed to examples of a lead frame that differ in the positions of recesses. In connection with the variations of the first embodiment, descriptions of the same components as those of the already described embodiment may be omitted.

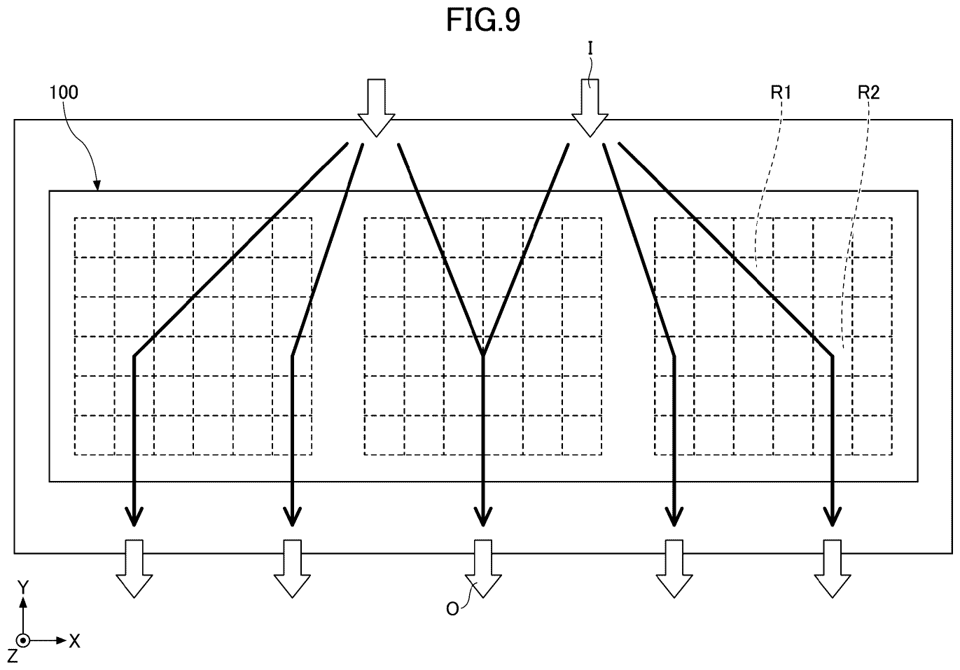

FIG. 9 is a drawing illustrating another example of the flow of resin for forming the resin portion. The direction I of resin injection and the direction O of air ventilation vary depending on the mold. It is thus preferable to arrange the recesses in accordance with the technical specifications of the mold.

In the example illustrated in FIG. 9, there are regions where the resin injected from the direction I and moving toward the direction O flows at an angle to the column direction (i.e., Y direction) and also regions where the resin flows substantially parallel to the column direction. In such a case, it is preferable that the first terminal portion 11 of one region R and the first terminal portion 11 of another region R have recesses 11y extending in different directions.

For example, in the region R1 illustrated in FIG. 9, the resin flows at an angle to the column direction. In contrast, in the region R2, the resin initially flows at an angle to the column direction but begins to flow substantially parallel to the column direction at an intermediate position. In such a case, it is preferable to use the recesses 11y in the first terminal portion 11 that differ in direction for the regions R1 and R2.

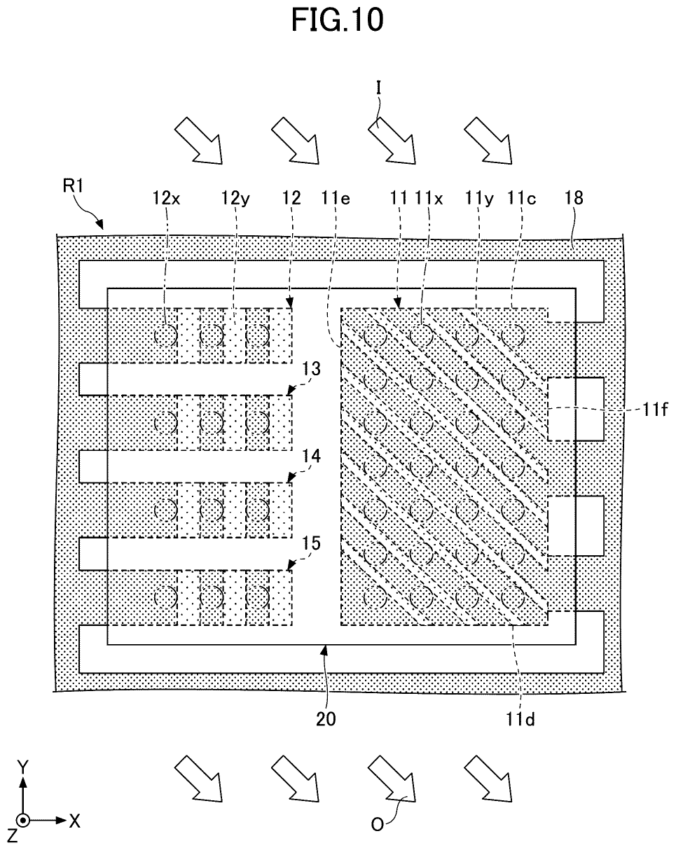

FIG. 10 is a plan view illustrating an example of a lead frame according to a first variation of the first embodiment. In the region R1 illustrated in FIG. 9, the first terminal portion 11 preferably has recesses 11y extending at an angle to the column direction (i.e., Y direction) as illustrated in FIG. 10. In a plan view, the recesses 11y may include those reaching the side surfaces 11c and 11f of the first terminal portion 11, those reaching the opposite side surfaces 11e and 11f of the first terminal portion 11, and those reaching the side surfaces 11e and 11d of the first terminal portion 11. Although resin flow is improved when at least one such recess 11y is provided, resin flow is further improved when a large number of recesses 11y are provided as illustrated in FIG. 10. It may be noted that, depending on the resin flow from the injection direction I toward the air ventilation direction O, all the regions R may have the structure illustrated in FIG. 10.

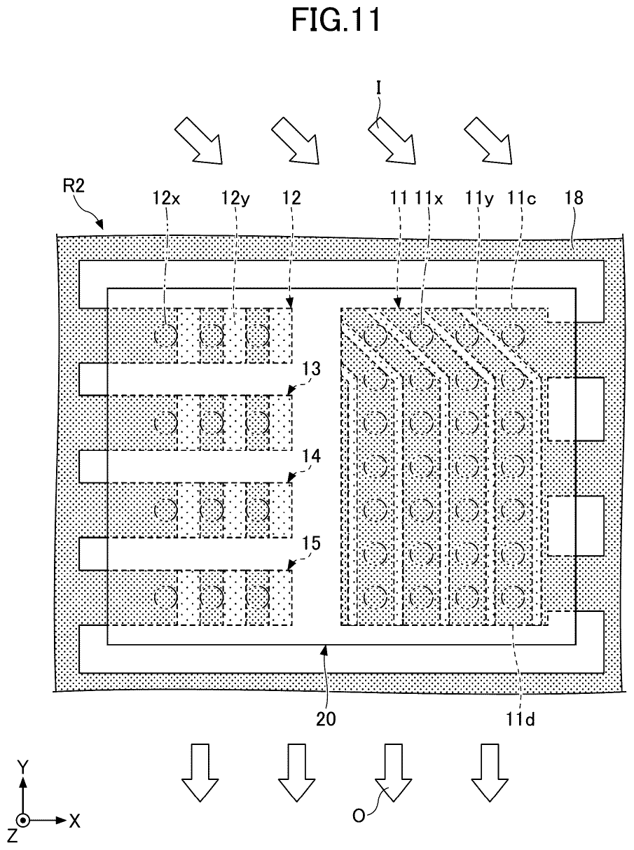

FIG. 11 is a plan view illustrating an example of a lead frame according to a second variation of the first embodiment. In the region R2 illustrated in FIG. 9, the first terminal portion 11 preferably has, as illustrated in FIG. 11, recesses 11y each of which has a portion extending at an angle to the column direction (i.e., Y direction) and a portion extending substantially parallel to the column direction. Provision of at least one such recess 11y improves the flow of resin, but provision of a large number of recesses 11y as illustrated in FIG. 11 further improves the flow of resin.

In the examples illustrated in FIGS. 10 and 11, the second terminal portion 12 to the fifth terminal portion 15 are provided with recesses substantially parallel to the column direction, but it is preferable that the directions of the recesses provided in the second terminal portion 12 to the fifth terminal portion 15 are also aligned with the directions of the recesses 11y.

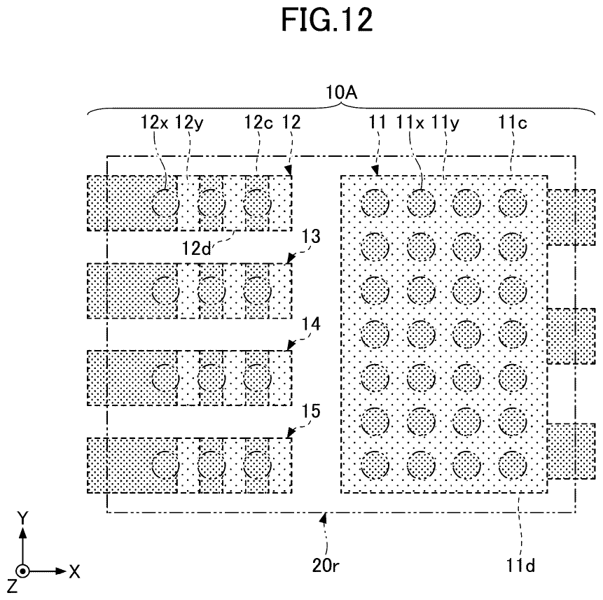

FIG. 12 is a plan view illustrating an example of a lead frame according to a third variation of the first embodiment. In a lead frame 10A illustrated in FIG. 12, the first terminal portion 11 has one recess 11y arranged in a grid pattern between all adjacent rows and between all adjacent columns. This arrangement greatly increases the ease of resin flow when the resin portion 40 is formed upon mounting the semiconductor chip 20 on the lead frame 10A, thereby greatly reducing the risk of void formation.

It may be noted that when a recess is formed by performing half etching over a wide area of the lead frame as in the example illustrated in FIG. 12, the balance of the internal stress of the material constituting the lead frame may be lost, which may result in warping of the lead frame. A large warpage generates gaps between the electrodes of the semiconductor chip and the bonding areas of the lead frame when mounting the semiconductor chip, which makes the mounting process difficult. In the case in which the warpage becomes a problem, thus, it is preferable to limit the area in which the recess is formed, as in the example illustrated in FIG. 2.

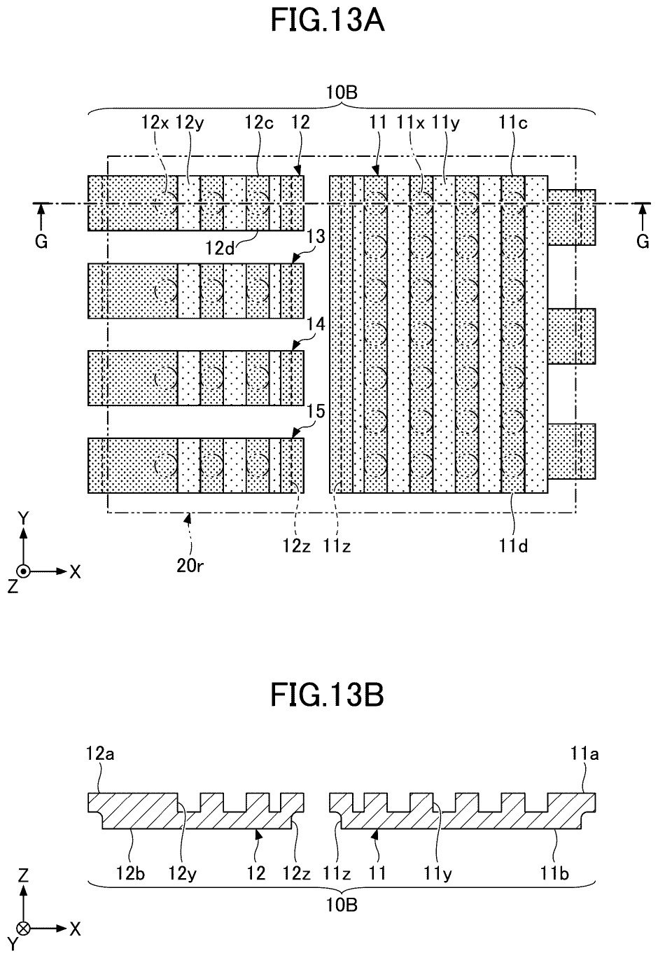

FIGS. 13A and 13B are drawings illustrating an example of a lead frame according to a fourth variation of the first embodiment. FIG. 13A is a plan view, and FIG. 13B is a cross-sectional view taken along the line G-G in FIG. 13A. In a lead frame 10B illustrated in FIGS. 13A and 13B, the first terminal portion 11 has a recess 11z that opens on the lower surface 11b at a position that does not overlap the recess 11y in plan view. Specifically, one recess 11z extending in the Y direction is provided at each of the two edge areas of the first terminal portion 11, opposite to each other in the X direction. The second terminal portion 12 has a recess 12z that opens on the lower surface 12b at a position that does not overlap the recess 12y in plan view. Specifically, one recess 12z extending in the Y direction is provided at each of the two edge areas of the second terminal portion 12, opposite to each other in the X direction. The third terminal portion 13 to the fifth terminal portion 15 are also provided with recesses at the same positions as the second terminal portion 12.

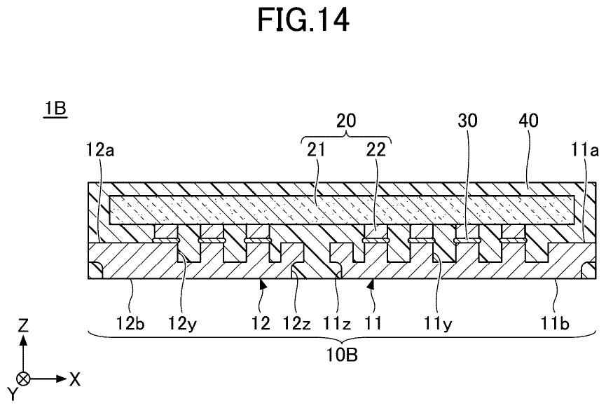

FIG. 14 is a cross-sectional view illustrating an example of a semiconductor device according to the fourth variation of the first embodiment. As illustrated in FIG. 14, a semiconductor device 1B is structured such that the resin portion 40 enters the recesses 11z, 12z, and the like provided in the first terminal portion 11 to the fifth terminal portion 15. This arrangement creates an anchoring effect, thereby reducing the likelihood of the resin portion 40 coming off the lead frame 10B.

In the first terminal portion 11 to the fifth terminal portion 15 illustrated in FIG. 13, the recesses arranged outside the mounting region 20r are situated at the cutting positions for singulating the semiconductor device including the lead frame. By providing the recesses opening to the lower surface in the terminal portions at the cutting positions for singulating the semiconductor device, and thus reducing the thickness of the terminal portions, the amount of the metal plate that needs to be cut, which is harder than the resin portion, is reduced. This facilitates the cutting process. Further, reducing the amount of the metal plate to be cut reduces the amount of burrs generated at the cut portions. Also, reducing the amount of the metal plate to be cut effectively prolongs the life of the blade of the dicer used for cutting.

According to at least one embodiment, a lead frame has a structure that prevents void formation between the lead frame and a semiconductor chip when injecting resin upon mounting the semiconductor chip.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment(s) of the present inventions have been described in detail, it should be understood that the various changes, substitutions, and alterations could be made hereto without departing from the spirit and scope of the invention.

What is claimed is:

1. A lead frame comprising
a plurality of terminal portions including a first terminal portion,
wherein the first terminal portion has an upper surface and at least one side surface, and includes:
a plurality of bonding areas that are defined on the upper surface within a mounting region where a semiconductor chip is to be mounted, the bonding areas being designated for bonding with respective electrodes of the semiconductor chip; and
a recess that is provided between adjacent bonding areas among the plurality of bonding areas and that opens on the upper surface, the recess reaching the at least one side surface.

2. The lead frame as claimed in claim 1, wherein the first terminal portion has another side surface situated opposite the one side surface, and the recess also reaches the another side surface.

3. The lead frame as claimed in claim 1, wherein the plurality of bonding areas are arranged in one or more rows and columns in plan view, and the recess is arranged between a pair of adjacent columns among the columns.

4. The lead frame as claimed in claim 3, wherein the first terminal portion has a plurality of said recesses, and the recesses are arranged between all adjacent ones of the columns.

5. The lead frame as claimed in claim 1, wherein the plurality of bonding areas are arranged in rows and columns in plan view, and the recess is arranged in a grid pattern between all adjacent ones of the rows and between all adjacent ones of the columns.

6. The lead frame as claimed in claim 1, wherein the plurality of bonding areas are arranged in one or more rows and columns in plan view, and the recess extends at an angle to a direction in which the columns extend.

7. The lead frame as claimed in claim 1, wherein the plurality of bonding areas are arranged in one or more rows and columns in plan view, and the recess has a portion thereof extending at an angle to a direction in which the columns extend, and also has a portion thereof extending in the direction in which the columns extend.

8. The lead frame as claimed in claim 1, wherein the first terminal portion has a lower surface, opposite the upper surface, and has a second recess that opens on the lower surface at a position not overlapping the recess that opens on the upper surface in plan view.

9. A semiconductor device comprising:
the lead frame of claim 1;
a semiconductor chip mounted on the lead frame; and
a resin portion encapsulating the semiconductor chip on the lead frame,
wherein the resin portion fills a gap between an upper surface of each of the terminal portions and a lower surface of the semiconductor chip, and also fills the recess, and
wherein a lower surface of each of the terminal portions is exposed outside the resin portion.

10. A metal plate comprising
a plurality of regions to be singulated into lead frames,
wherein each of the regions has a plurality of terminal portions including a first terminal portion,
wherein the first terminal portion has an upper surface and at least one side surface, and includes:
a plurality of bonding areas that are defined on the upper surface within a mounting region where a semiconductor chip is to be mounted, the bonding areas being designated for bonding with respective electrodes of the semiconductor chip; and
a recess that is provided between adjacent bonding areas among the plurality of bonding areas and that opens on the upper surface, the recess reaching the at least one side surface, and
wherein the recess of the first terminal portion of one of the regions and the recess of the first terminal portion of another one of the regions extend in different directions from each other.
